(19) United States
(12) Patent Application Publication
(10) Pub. No.: US 2020/0096533 A1
(43) Pub. Date: Mar. 26, 2020

(54) PIEZOELECTRIC CERAMIC STRUCTURE AND PIEZOELECTRIC ACCELERATION SENSOR HAVING THE SAME

(71) Applicant: FATRI United Testing & Control (Quanzhou) Technologies Co., Ltd., Quanzhou City (CN)

(72) Inventors: Nie Yongzhong, Quanzhou City (CN); Nie Chuan, Quanzhou City (CN); Zeng Tingfang, Quanzhou City (CN)

(21) Appl. No.: 16/398,579

(22) Filed: Apr. 30, 2019

(30) Foreign Application Priority Data
Sep. 20, 2018 (CN) 201821544345.3

(51) Int. Cl. G01P 15/09; H01L 41/187; H01L 41/113; H01L 41/047

(52) U.S. Cl. CPC G01P 15/09; H01L 41/1873; H01L 41/0472; H01L 41/1132; H01L 41/0471; H01L 41/1878

(57) ABSTRACT

The present disclosure relates to the technical field of sensors, in particular to a piezoelectric ceramic structure, comprising at least one first piezoelectric layer and at least one second piezoelectric layer stacked on each other, wherein the first piezoelectric layer having a first structure in which a piezoelectric coefficient decreases as temperature increases, and the second piezoelectric layer having a second structure in which a piezoelectric coefficient increases as temperature increases, and an electrode layer is disposed between the first piezoelectric layer and the second piezoelectric layer, and disposed on exposed end surfaces of the first piezoelectric layer and the second piezoelectric layer. A piezoelectric acceleration sensor having the above piezoelectric ceramic structure is also provided. The present disclosure provides a piezoelectric ceramic structure with good high temperature properties and a piezoelectric acceleration sensor having the same.

### CROSS REFERENCE TO RELATED APPLICATIONS

This application claims priority to Chinese Patent Application No. 201821544345.3, filed on Sep. 20, 2018, the entire contents of which are incorporated herein by reference.

### TECHNICAL FIELD

The present disclosure relates to the technical field of sensors, in particular to a piezoelectric ceramic structure and a piezoelectric acceleration sensor having the same.

### BACKGROUND

When the piezoelectric acceleration sensor works under high temperature conditions, the amplifying circuit and the piezoelectric element of the sensor fail easily. Due to the fact that the different expansion coefficients among various materials, the stress value fluctuates greatly, which affects high temperature characteristics of the piezoelectric acceleration sensor, especially in high temperature environments. The temperature drift of piezoelectric materials at high temperatures is also serious.

### SUMMARY

Therefore, the technical problem to be solved by the present disclosure is to overcome the defects in the prior art that the high temperature characteristic of the piezoelectric acceleration sensor is affected by different expansion coefficients among various materials of the piezoelectric acceleration sensor under the high temperature environment, thereby providing a piezoelectric ceramic structure with good high temperature characteristics and a piezoelectric acceleration sensor having the same.

In order to solve the above technical problems, the present disclosure provides a piezoelectric ceramic structure, comprising:
at least one first piezoelectric layer and at least one second piezoelectric layer stacked on each other, wherein, the first piezoelectric layer has a first structure, in which a piezoelectric coefficient decreases as temperature increases, and the second piezoelectric layer has a second structure in which a piezoelectric coefficient increases as temperature increases, and an electrode layer is disposed between the first piezoelectric layer and the second piezoelectric layer, and disposed on exposed end surfaces of the first piezoelectric layer and the second piezoelectric layer.

Further, the first piezoelectric layer is a bismuth layer ceramic sheet, and the second piezoelectric layer is a lithium niobate compensation sheet.

Further, the first piezoelectric layer and the second piezoelectric layer comprises at least two first piezoelectric layers and at least two second piezoelectric layers stacked on each other, and two adjacent first piezoelectric layers have one electrode layer disposed therebetween and two adjacent second piezoelectric layers also have one electrode layer disposed therebetween, and two adjacent electrode layers are of opposite polarities.

Further, the two electrode layers of the same polarity and disposed close to each other are connected in series.

Further, the electrode layer is a nickel-based alloy electrode.

The present disclosure also provides a piezoelectric acceleration sensor comprising the piezoelectric ceramic structure, and further comprising a locking member disposed to sequentially pass through through holes formed in the first piezoelectric layer, the electrode layer and the second piezoelectric layer stacked on each other, and the piezoelectric ceramic structure is placed in a housing.

Further, the locking member is a bolt.

Further, the piezoelectric acceleration sensor of the present disclosure also comprises an insulating layer disposed on both end faces of the piezoelectric ceramic structure in an axial direction.

Further, the piezoelectric acceleration sensor also comprises a mass block and an installation seat disposed on both sides of the insulating layer respectively, wherein the locking member is disposed to sequentially pass through the mass block, the piezoelectric ceramic structure and the installation seat and fixed on a bottom wall of the housing.

Further, all the locking member, the electrode layer and the installation seat are made of inconel.

The technical solution of the present disclosure has the following advantages:

1. In the piezoelectric ceramic structure provided by the present disclosure, the first piezoelectric layer has a first structure, in which the piezoelectric coefficient decreases as the temperature increases, and the second piezoelectric layer has a second structure in which the piezoelectric coefficient increases as the temperature increases. An electrode layer is disposed between the first piezoelectric layer and the second piezoelectric layer, and disposed on the exposed end surfaces of the first piezoelectric layer and the second piezoelectric layer respectively. At least one electrode layer is disposed on the first piezoelectric layer and the second piezoelectric layer respectively such that the temperature characteristics tendencies of both are opposite, and the second piezoelectric layer is disposed as a compensation layer for the first piezoelectric layer, thereby effectively avoiding significant fluctuation of the stress value caused by different expansion coefficients among various materials, which affects the high temperature characteristics, resulting in serious temperature drift of the piezoelectric material at high temperatures.

2. In the piezoelectric ceramic structure provided by the present disclosure, the bismuth layer ceramic sheet has a characteristic that the piezoelectric coefficient decreases as temperature increases and the lithium niobate compensation sheet has a characteristic that the piezoelectric coefficient increases as temperature increases. The Lithium niobate compensation sheet compensates the decrease of the piezoelectric coefficient as temperature increases such that the corresponding temperature characteristic curve of the temperature drift of the piezoelectric structure increases positively.

3. In the piezoelectric acceleration sensor provided by the present disclosure, the first piezoelectric layer, the electrode layer and the second piezoelectric layer are fixed in the housing through the locking member, which is easy for installation and convenient for later disassembly and maintenance, improves the rigidity of the entire structure greatly, and achieve good frequency response characteristics.

4. In the piezoelectric acceleration sensor provided by the present disclosure, an insulating layer is provided on both end faces of the piezoelectric ceramic structure in the axial direction, which can effectively prevent the electric charge from being exposed and improve the overall electrical conductivity of the piezoelectric ceramic structure.

5. In the piezoelectric acceleration sensor provided by the present disclosure, all the locking member, the electrode layer and the installation seat are made of Inconel, and the Inconel has the characteristics of maintaining high strength at a temperature of 650-1000° C., and the Inconel has a good linearity and improved anti-corrosion ability.

### BRIEF DESCRIPTION OF THE DRAWINGS

One or more embodiments are illustrated by way of example, and not by limitation, in the figures of the accompanying drawings, wherein elements having the same reference numeral designations represent like elements throughout. The drawings are not to scale, unless otherwise disclosed.

In order to illustrate the detailed description of the present disclosure or the technical solutions in the prior art more clearly, the drawings used in the detailed description or the description of the prior art will be briefly described below. Obviously, the drawings in the following description are used to illustrate some embodiments of the present disclosure, and those skilled in the art can obtain other drawings based on these drawings without paying any inventive labor.

FIG. 1 is a cross-sectional view of the piezoelectric acceleration sensor according to the present disclosure.

FIG. 2 is an enlarged view of circle A of FIG. 1.

FIG. 3 is a schematic view of the electrode sheet of FIG. 2.

### DESCRIPTION OF THE REFERENCE SIGNS

1—upper cover; 2—housing; 3—locking member; 4—mass block; 5—insulating layer; 6—electrode layer; 7—the second piezoelectric layer; 8—the first piezoelectric layer; 9—installation seat; 10—sealing gasket;

### DETAILED DESCRIPTION

The technical solutions of the present disclosure will be clearly and completely described in the following description with reference to the drawings. It is obvious that the described embodiments represent only part of but not all of the embodiments of the present disclosure. All the other embodiments obtained by those skilled in the art based on the embodiments of the present disclosure without paying any inventive effort fall in the scope of the present disclosure.

Further, the technical features involved in the different embodiments of the present disclosure described below may be combined with each other features as long as they do not conflict with each other.

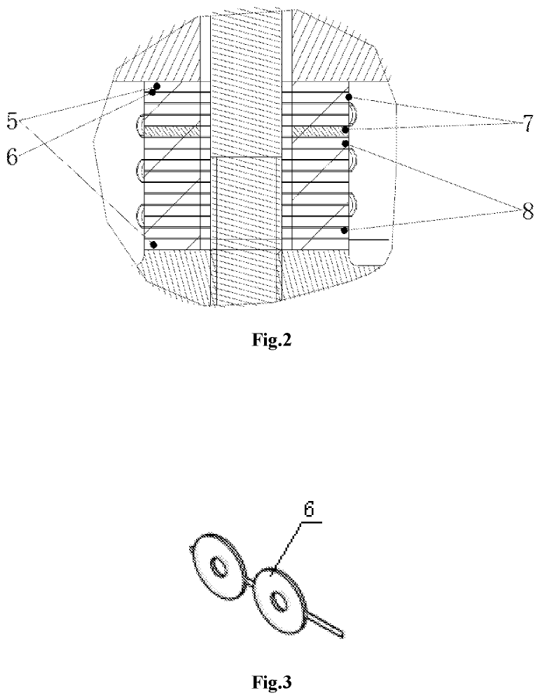

An embodiment of the piezoelectric ceramic structure as illustrated in FIG. 2-3 comprises at least one first piezoelectric layer 8 and at least one second piezoelectric layer 7 stacked on each other, wherein the first piezoelectric layer 8 has a first structure in which a piezoelectric coefficient decreases as temperature increases, and the second piezoelectric layer 7 has a second structure in which a piezoelectric coefficient increases as temperature increases. An electrode layer 6 is disposed between the first piezoelectric layer 8 and the second piezoelectric layer 7, and disposed on the exposed end surfaces of the first piezoelectric layer 8 and the second piezoelectric layer 7.

The above mentioned piezoelectric ceramic structure comprises at least one first piezoelectric layer and at least one second piezoelectric layer, wherein the first piezoelectric layer has a first structure in which a piezoelectric coefficient decreases as temperature increases, and the second piezoelectric layer has a second structure in which a piezoelectric coefficient increases as temperature increases. An electrode layer is disposed between the first piezoelectric layer and the second piezoelectric layer, and disposed on the exposed end surfaces of the first piezoelectric layer and the second piezoelectric layer. The problem of significant fluctuation of the stress value caused by different expansion coefficients among various materials, which affects the high temperature characteristics and results in serious temperature drift of the piezoelectric material at high temperature has been solved.

Specifically, the first piezoelectric layer 8 is a bismuth layer ceramic sheet, and the second piezoelectric layer 7 is a lithium niobate compensation sheet. The bismuth layer ceramic sheet has the characteristic that the piezoelectric coefficient decreases with increasing temperature. The lithium niobate compensation sheet has the characteristic that the piezoelectric coefficient increases with the increasing temperature. The temperature characteristic of the lithium niobate compensation sheet is opposite to that of the bismuth layer ceramic, that is, the characteristic curve of the sensitivity to temperature drift in respect to the temperature shows as a positively increasing function. The lithium niobate compensation sheet material acts as a compensation material layer, which compensates the decrease of the piezoelectric coefficient of the bismuth layer ceramic sheet as temperature increases. As shown in FIG. 2, the exposed end surface of the first piezoelectric layer 8 is the upper surface, and the exposed end surface of the second piezoelectric layer 7 is the lower surface. The electrode layer 6, the lithium niobate compensation sheet, the electrode layer 6, the bismuth layer ceramic sheet and the electrode layer are stacked in sequence from top to bottom, and there is no connecting layer or glue in the middle, which makes the connection among all the layers a rigid contact, and the overall rigidity and frequency response characteristics are good.

The piezoelectric ceramic structure comprise at least two first piezoelectric layers 8 and at least two second piezoelectric layers 7 stacked on each other, and two adjacent first piezoelectric layers 8 have one electrode layer 6 disposed therebetween and two adjacent second piezoelectric layers 7 also have one electrode layer 6 disposed therebetween, and two adjacent electrode layers 6 are of opposite polarities. In particular, the two electrode layers 6 of the same polarity and disposed close to each other are connected in series.

As shown in FIG. 2, the two electrode layers 6 connected in series on both sides of the axis of the piezoelectric ceramic structure are folded in U shape and staggered. Specifically, the first U-shaped folded electrode layer on the left side of the axis is each disposed on the upper surface of the second piezoelectric layer 7 at the top and the lower surface of the adjacent second piezoelectric layer 7. The U-shaped folded electrode layer on the right side of the axis is each disposed on the upper surface of the second piezoelectric layers 7 which is the fourth counted from top to bottom and the lower surface of the first piezoelectric layer 8 which is the first one, and the two U-shaped folded electrodes are of the opposite polarities, another sheet-shaped electrode having the opposite polarity is provided between the same U-shaped folded electrodes, thereby forming a structure in which the positive and negative polarities of the same side are alternately arranged. In this embodiment, the first piezoelectric layer 8 is provided with four layers, and the second piezoelectric layer 7 is provided with nine layers.

The electrode layer 6 is a nickel-based alloy electrode. The inconel has the characteristics of maintaining high strength at a temperature of 650-1000° C., and has improved anti-oxidation corrosion ability.

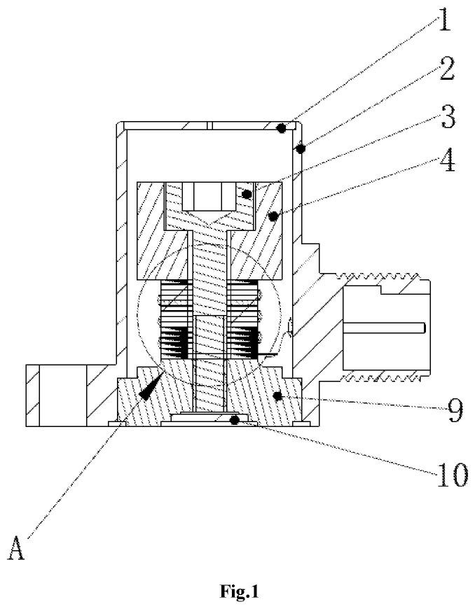

As shown in FIG. 1, the present disclosure also provides a piezoelectric acceleration sensor comprising the piezoelectric ceramic structure, further comprising a locking member 3 sequentially passing through a through hole formed in the first piezoelectric layer 8, the electrode layer 6 and the second piezoelectric layer 7 stacked on each other, and the piezoelectric ceramic structure is placed in a housing 2.

As an embodiment, the locking member 3 is a bolt. The bolt connection has some advantages, for example, it is easy to assemble and disassemble, the pre-tightening force can be increased to prevent loosening, and the phase change of the material at the joint can be avoided.

As an alternative embodiment, the locking member 3 can also be a center column, a screw or the like.

An insulating layer 5 is further provided on two end faces of the piezoelectric ceramic structure in the axial direction. This arrangement effectively improves the overall electrical conductivity of the piezoelectric ceramic structure, and prevents the electric charge from coming out of the piezoelectric ceramic structure.

A mass block 4 and an installation seat 9 are further provided on both sides of the insulating layer 5. The locking member 3 is configured to sequentially pass through the mass block 4, the piezoelectric ceramic structure and the installation seat 9 and fixed on a bottom wall of the housing 2. The installation seat 9 also has a sealing gasket 10 in the shape of cylindrical boss disposed therein, so that it may effectively increase the output of the electric charge and make the piezoelectric ceramic structure more sensitive.

The locking member 3, the electrode layer 6 and the installation seat 9 are all made of inconel. The inconel has the characteristic of maintaining high strength at a temperature of 650-1000° C., and has improved anti-oxidation corrosion ability.

Obviously, the above-described embodiments are only examples for clear illustration, and are not intended to limit the embodiments. Other variations or modifications in the various forms can be made by those skilled in the art based on the above description. There is no need and no way to exhaust all of the embodiments. The obvious changes or variations derived therefrom are still within the scope of protection claimed by the present disclosure.

What is claimed is:

1. A piezoelectric ceramic structure, comprising:
at least one first piezoelectric layer and at least one second piezoelectric layer stacked on each other,
wherein,
the first piezoelectric layer has a first structure, in which a piezoelectric coefficient decreases as temperature increases, and
the second piezoelectric layer has a second structure in which a piezoelectric coefficient increases as temperature increases, and
an electrode layer is disposed between the first piezoelectric layer and the second piezoelectric layer, and disposed on exposed end surfaces of the first piezoelectric layer and the second piezoelectric layer.

2. The piezoelectric ceramic structure of claim 1, wherein the first piezoelectric layer is a bismuth layer ceramic sheet and the second piezoelectric layer is a lithium niobate compensation sheet.

3. The piezoelectric ceramic structure of claim 1, comprising at least two first piezoelectric layers and at least two second piezoelectric layers stacked on each other, and two adjacent first piezoelectric layers have one electrode layer disposed therebetween and two adjacent second piezoelectric layers also have one electrode layer disposed therebetween, and two adjacent electrode layers are of opposite polarities.

4. The piezoelectric ceramic structure of claim 3, wherein, the two electrode layers of the same polarity and disposed close to each other are connected in series.

5. The piezoelectric ceramic structure of claim 1, wherein, the electrode layer is a nickel-based alloy electrode.

6. A piezoelectric acceleration sensor, comprising
a piezoelectric ceramic structure of any of claim 1,
further comprising a locking member sequentially passing through a through hole formed in the first piezoelectric layer, the electrode layer and the second piezoelectric layer stacked on each other, and the piezoelectric ceramic structure is placed in a housing.

7. The piezoelectric acceleration sensor of claim 6, wherein the locking member is a bolt.

8. The piezoelectric acceleration sensor of claim 6, further comprising an insulating layer disposed on both end faces of the piezoelectric ceramic structure in the axial direction.

9. The piezoelectric acceleration sensor of claim 8, further comprising
a mass block and an installation seat disposed on both sides of the insulating layer respectively,
wherein,
the locking member is disposed to sequentially pass through the mass block, the piezoelectric ceramic structure and the installation seat and fixed on a bottom wall of the housing.

10. The piezoelectric acceleration sensor of claim 9, wherein all the locking member, the electrode layer and the installation seat are made of inconel.

11. The piezoelectric ceramic structure of claim 2, comprising at least two first piezoelectric layers and at least two second piezoelectric layers stacked on each other, and two adjacent first piezoelectric layers have one electrode layer disposed therebetween and two adjacent second piezoelectric layers also have one electrode layer disposed therebetween, and two adjacent electrode layers are of opposite polarities.

12. The piezoelectric ceramic structure of claim 11, wherein, the two electrode layers of the same polarity and disposed close to each other are connected in series.

13. The piezoelectric acceleration sensor of claim 6, wherein the first piezoelectric layer is a bismuth layer ceramic sheet and the second piezoelectric layer is a lithium niobate compensation sheet.

14. The piezoelectric acceleration sensor of claim 6, comprising at least two first piezoelectric layers and at least two second piezoelectric layers stacked on each other, and two adjacent first piezoelectric layers have one electrode layer disposed therebetween and two adjacent second piezoelectric layers also have one electrode layer disposed therebetween, and two adjacent electrode layers are of opposite polarities.

15. The piezoelectric acceleration sensor of claim 6, wherein the two electrode layers of the same polarity and disposed close to each other are connected in series.

16. The piezoelectric acceleration sensor of claim 6, wherein the electrode layer is a nickel-based alloy electrode.
